(19) United States
(12) Patent Application Publication
(10) Pub. No.: US 2014/0131198 A1
(43) Pub. Date: May 15, 2014

(54) SOLAR CELL FORMATION APPARATUS AND METHOD

(71) Applicant: TSMC SOLAR LTD., Taichung City (TW)

(72) Inventors: Edward TENG, Sunnyvale, CA (US); Ying-Chen CHAO, Hsinchu City (TW); Chih-Jen YANG, Taichung City (TW)

(73) Assignee: TSMC SOLAR LTD., Taichung City (TW)

(21) Appl. No.: 13/672,851

(22) Filed: Nov. 9, 2012

(51) Int. Cl. H01L 31/18

(52) U.S. Cl. CPC H01L 31/18
USPC 204/298.07; 204/298.11; 204/298.28; 204/298.08

(57) ABSTRACT

Apparatuses for forming material films on a solar cell substrate of substantially uniform thickness and processes for forming the same are disclosed. The process performed in the apparatuses is physical vapor deposition (PVD) in some embodiments. In one embodiment, an apparatus includes a specially configured flow aperture. In another embodiment, an apparatus includes moveable shutters which open and close in synchronization with a rotating drum on which substrates are mounted for processing. In other embodiments, the apparatus includes a variable power supply or drum speed control which automatically vary the power supply to the apparatus or drum speed respectively in synchronization with the rotating drum.

### FIELD

The present disclosure generally relates to photovoltaic solar cells, and more particularly to thin film solar cells and methods for forming same.

### BACKGROUND

Thin film photovoltaic (PV) solar cells are one class of energy source devices which harness a renewable source of energy in the form of light that is converted into useful electrical energy which may be used for numerous applications. Thin film solar cells are multi-layered semiconductor structures formed by depositing various thin layers and films of semiconductor and other materials on a substrate. These solar cells may be made into light-weight flexible sheets in some forms comprised of a plurality of individual electrically interconnected cells. The attributes of light weight and flexibility gives thin film solar cells broad potential applicability as an electric power source for use in portable electronics, aerospace, and residential and commercial buildings where they can be incorporated into various architectural features such as roof shingles, facades, and skylights.

Thin film solar cells generally include, in order, a rear substrate such as glass, polymer, or metal, a bottom electrode layer (also referred to as a “back contact”), an active p-type light absorber layer, a buffer layer, and an n-type transparent conductive oxide (TCO) top electrode layer. The solar cell is typically completed with an EVA-butyl encapsulant applied directly onto the top electrode layer, followed by applying a protective top cover such as glass or polymer.

Chalcogenide materials have been used for absorber layers. Copper indium gallium diselenide (CIGS) is one commonly used chalcogenide absorber layer material in thin film solar cells. CIGS-based thin film solar cells have achieved excellent conversion efficiencies (e.g. over 20% in laboratory environments). One method used for depositing CIGS thin films is a sequential two-step sputtering electrodeposition-selenization process. First, copper, gallium, and indium are sputtered onto the substrate using appropriate material targets to form a CIG precursor film. Next, selenization is performed which involves reacting the CIG precursor film with Se vapor or H2Se gas to complete the CIGS absorber layer film.

The sputtering-selenization process is sometimes performed in a PVD (physical vapor deposition) apparatus having a rotating drum on which multiple solar cell substrates are mounted as they undergo the absorber layer deposition/formation process. Such apparatuses have been prone to producing CIGS film thicknesses which are typically thicker at the substrate edges than in the center regions. This problem is most pronounced when processing larger spinning or rotating substrates. Since absorber layer thickness uniformity of deposited CIGS films will affect the solar cell efficiency, thickness non-uniformity in general is undesirable.

An improved thin film solar cell is therefore desired that addresses the foregoing problems.

### BRIEF DESCRIPTION OF THE DRAWINGS

The features of the preferred embodiments will be described with reference to the following drawings where like elements are labeled similarly, and in which:

FIG. 1 is a top cross-sectional plan view of a first embodiment of a sputtering apparatus for forming thin films on a solar cell substrate according to the present disclosure;

FIG. 2 is an isometric view of a sputtering source enclosure of the apparatus of FIG. 1;

FIGS. 3 and 4 are a top cross-sectional plan views of an openable/closeable shutter system useable in the apparatus of FIG. 1;

FIG. 5 is an isometric frontal elevation view of the enclosure of FIG. 2 having a specially configured flow aperture;

FIG. 6 is an isometric frontal elevation view of the enclosure of FIG. 2 and shutter system of FIGS. 3 and 4;

FIG. 7 is frontal elevation view of a sputtering source target useable in the apparatus of FIG. 1;

FIG. 8 is top cross-sectional plan view of an alternative rotatable drum for holding substrates that is useable in the sputtering apparatus of FIG. 1;

FIG. 9 is a schematic top view diagram of a substrate and sputtering target showing a path of travel of the substrate with respect to the target during rotation of the drum of FIG. 8; and

FIG. 10 is a graph showing a drum speed control profile curve useable for controlling the speed of the drum of FIG. 8 for improving film thickness uniformity.

All drawings are schematic and are not drawn to scale.

### DETAILED DESCRIPTION

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that can exist alone or in other combinations of features; the scope of the disclosure being defined by the claims appended hereto. The terms “chip” and “die” are used interchangeably herein.

According to the present disclosure, the inventors have discovered that better CIGS absorber layer film thickness uniformity can be achieved by one or more improvements in the film deposition apparatus design and/or operation of the process. These improvements include the following, as further described herein: (a) the film thickness uniformity in the vertical direction along the substrate can be improved with a specially designed shield which can be controlled from outside vacuum chamber of the sputtering apparatus; (b) the film thickness uniformity in the horizontal direction along the substrate can be improved by a mechanically operated shutter which is synchronized with the rotating substrate carousel or drum speed; (c) the film thickness uniformity in the horizontal direction along the substrate can be improved by an electronically controlled sputtering power supply which is synchronized with the spinning drum speed; and (d) the film thickness uniformity in the horizontal direction along the substrate can be improved by adjusting the drum rotational speed which is synchronized with the distance between rotated substrate and the stationary sputtering target. Advantageously, these foregoing improvements enhance CIGS absorber layer film thickness uniformity thereby improving solar cell performance and efficiency.

The foregoing improvements will now be described in further detail.

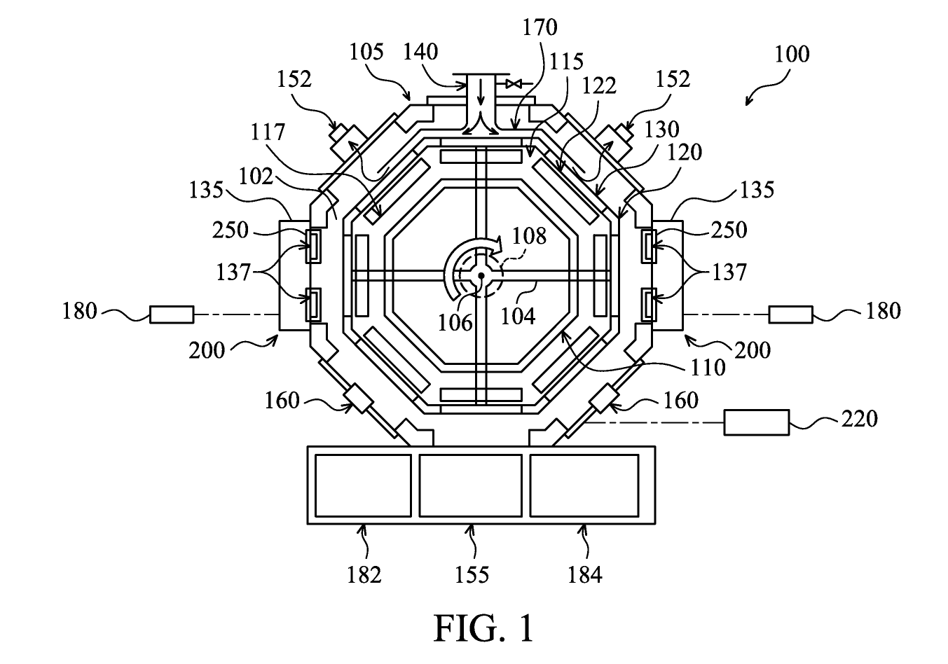

FIG. 1 is a top view showing one exemplary embodiment of a physical vapor deposition (PVD) apparatus 100 for forming an absorber layer film according to the present disclosure. Apparatus 100 includes a housing 105 defining a vacuum chamber 102 therein. Vacuum chamber 102 may be annular shaped in some embodiments. In various embodiments, without limitation, the housing 105 may be shaped as a polygon. For example, as shown in the illustrated embodiment, the housing 105 may be octagonally shaped. In various other possible embodiments, the polygonal housing may be shaped as a hexagon, decahedron, or other suitable shape. Housing 105 may include one or more removable doors disposed on one or more sides of the vacuum chamber 102. The housing 105 may be formed of metal such as stainless steel in some embodiments or other suitable metals and alloys used for sputtering apparatuses.

In one representative exemplary embodiment, without limitation, housing 105 can define a single vacuum chamber 102 therein having a height of approximately 2.4 m (e.g. 2.3 m to 2.5 m) with a length and width of approximately 9.8 m (e.g. 9.7 m to 9.9 m).

With continuing reference to FIG. 1, the PVD apparatus 100 includes a spinning and rotatable substrate support drum 120 configured to releasably support and hold a plurality of substrates 130 (see also FIG. 7) on a plurality of vertical substrate support surfaces 122 provided on the drum. Surfaces 122 face radially outwards from drum 120 towards interior surfaces of the vacuum chamber 102 defined by housing 105 as shown so that the substrates may be presented to one or more stationary sputtering sources 135 arranged around the drum and an evaporation source 140 for depositing selenium on the substrate.

Referring to FIG. 7, which is a front elevation view of substrate 130 as it would be positioned when mounted on substrate support drum 120, the substrates are substantially flat and polygonal in configuration in some embodiments including a top edge 131, bottom edge 132, and an opposing pair of side edges 133. In the embodiment shown, substrate 130 is rectilinear in shape. Any suitable planar or flat rigid thin film solar cell substrate material may be used that can be mounted to substrate support drum 120. In some embodiments, substrates 130 include for example, rigid glass such as lime glass. In other possible embodiments, substrates 130 include other solar cell substrate materials such as rigid metal or plastic sheets. Typical representative dimensions of substrates 130 that may be processed in PVD apparatus 100 include, without limitation, those that measure approximately 60-100 cm wide and 1.5-2.0 m high. Other suitable sized substrates may be used.

With continuing reference to FIG. 1, substrate drum 120 is rotatable about and defines a central vertical rotational axis in the vacuum chamber 102. Although FIG. 1 illustrates a clockwise direction of rotation for the drum 120, in some embodiments drum 120 is configured and arranged to rotate in a counter-clockwise direction. In various embodiments, the rotatable substrate drum 120 is operatively coupled to a drive shaft rotated by an electric motor drive 108 or other drive mechanism mounted to apparatus 100 and operable to spin and rotate the drum. Motor drive in various embodiments may be mounted on the top or bottom of the apparatus housing 105. In one embodiment, without limitation, a variable speed electric motor is used for motor drive 108 which is controlled by an appropriately configured motor speed controller operable to rotate substrate drum 120 at a constant speed and/or variable speeds, as further described herein. In some embodiments, a programmable controller 220 controls the speed of the motor drive shaft.

In some embodiments, substrate drum 120 is rotated at a speed, for example, between approximately 5 and 100 RPM (e.g. 3 and 105 RPM). In various embodiments, a speed of rotation (revolutions per minute or RPM) of the rotatable substrate drum 120 is selected to minimize excessive deposition of absorber layer components on the plurality of substrates 130. In one exemplary embodiment, substrate drum 120 rotates at a speed of approximately 80 RPM (e.g. 75-85 RPM). In some embodiments, the apparatus 100 includes a rotatable inner drive cylinder 110 disposed inside substrate drum 120 and movably coupled to the motor drive supported by housing 105. As shown, the rotatable inner drive cylinder 110 is operatively coupled to concentrically arranged outer substrate drum 120 via one or more support arms 104 extending radially outwards from a hub 106 directly or indirectly coupled to a drive shaft of the motor drive. As shown, in one embodiment without limitation, the inner drive cylinder 110 has a shape that is substantially conformal and complementary with the shape of the substrate drum 120 (i.e. polygonal). However, the drive cylinder 110 can have any suitable shape including circular.

With continuing reference to FIG. 1, PVD apparatus 100 includes a sputtering system 200 including at least one sputtering source 135 configured to deposit a plurality of absorber layer atoms of a first type over at least a portion of a surface of each one of the plurality of substrates 130. In some embodiment sputtering system 200 includes two sputtering sources 135 which may be arranged in diametrically opposing positions as shown. Sputtering sources 135 are operable to deposit atoms of copper, indium, and gallium onto substrates 130 as they rotate past the sputtering sources for forming a CIGS absorber layer of a thin film solar cell. Any suitable number of sputtering sources may be provided depending on the number and nature of materials to be deposited onto solar cell substrates 130.

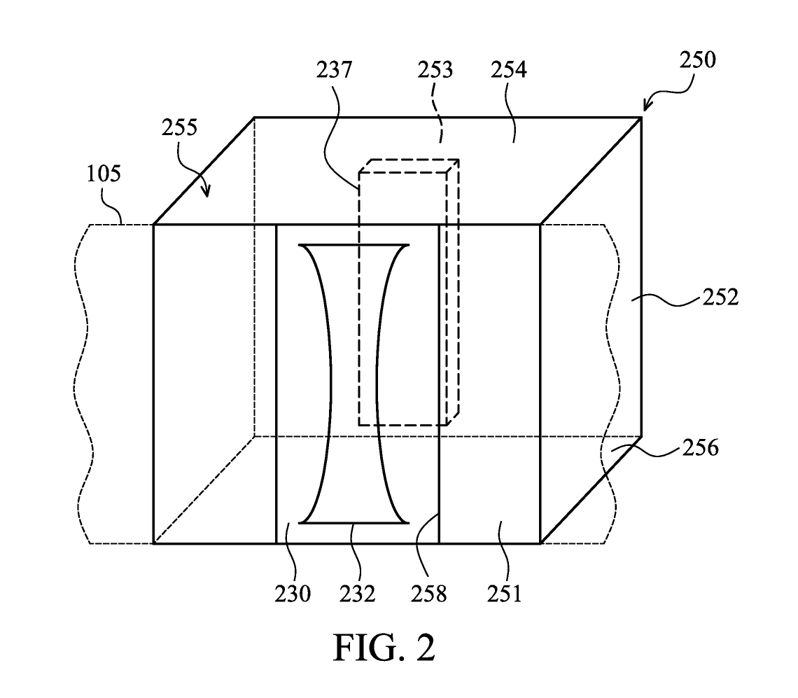

In one embodiment, sputtering source 135 is disposed in a shielding box enclosure 250 attached to housing 105 and configured to physically communicate with vacuum chamber 102 formed inside housing 105 as shown in FIGS. 1 and 2. In one embodiment, sputtering source 135 is mounted outboard of the vacuum chamber 102 on housing 105 as shown being positioned and disposed on an exterior portion of the vacuum chamber 102. Sputtering source 135 and other appurtenances of the sputtering system 200 are supported by box enclosure 250 in one embodiment, as further described herein.

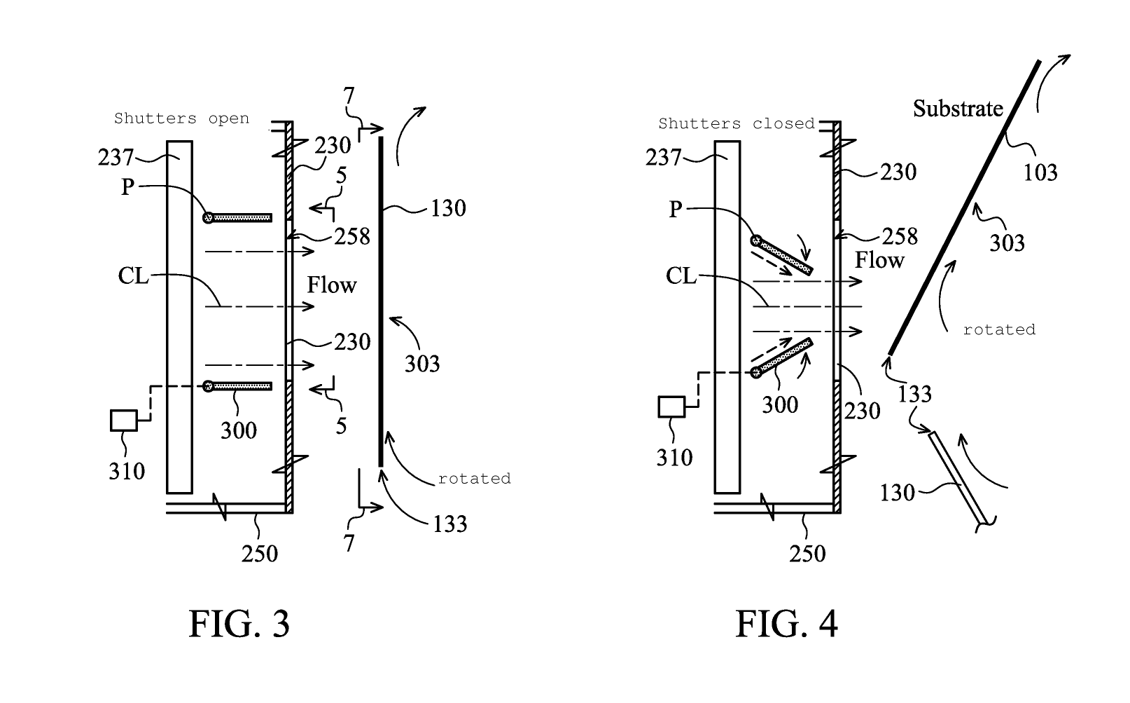

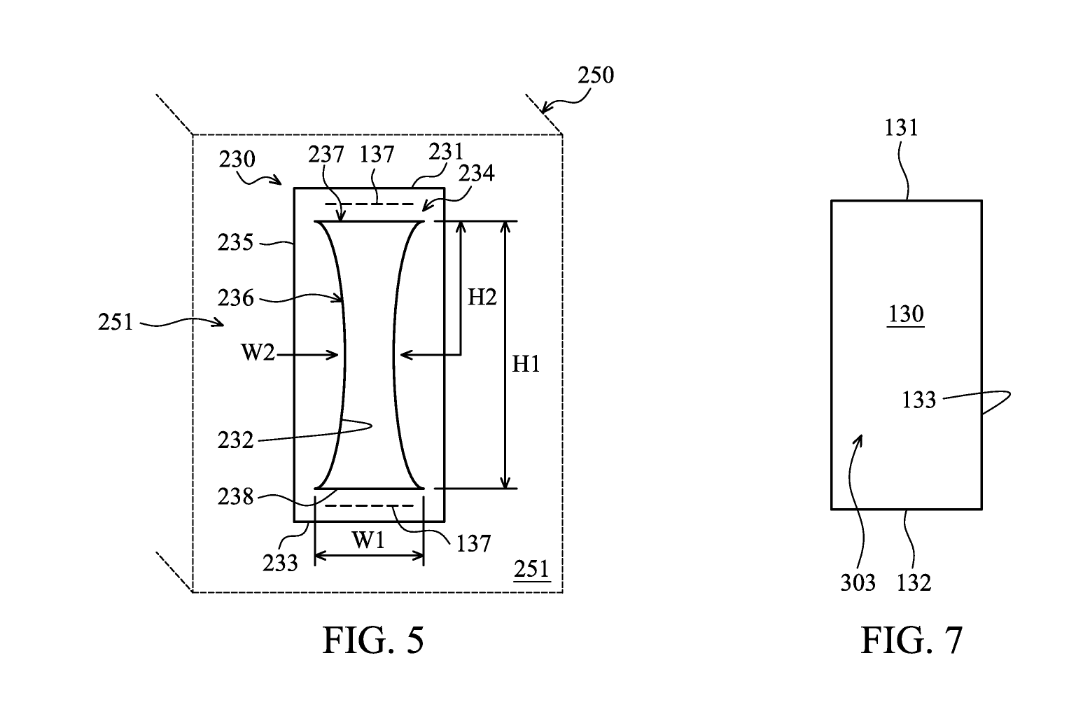

FIG. 2 is a perspective view of the shielding box enclosure 250 viewed from inside vacuum chamber 102 looking outwards. In one embodiment, box enclosure 250 comprises a structural support frame including a front wall 251, rear wall 253, a pair of opposing sidewalls 252 connecting the front and rear walls, a top wall 254, and a bottom wall 256. The walls define an internal cavity 255 which contains and supports sputtering source 135, stationary targets 137, pivotable shutters 300 (see, e.g. FIGS. 3-4), and other appurtenances. Front wall 251 defines a flow opening which in one embodiment is a frontal opening 258 in front wall 251 that extends vertically and horizontally to provide an open flow communication pathway between cavity 255 and vacuum chamber 102 of PVD apparatus 100 that is configured and operable to allow the passage of sputtering or carrier gas and absorber layer film components from targets 137 to strike and form a layer on substrates 130 positioned on rotatable drum 120. In other embodiments, the flow opening may be formed by flow aperture 232 of a shield plate 230 as further described herein (see, e.g. FIGS. 2 and 5). Enclosure 250 may be made of any suitable material, including for example metals such as stainless steel in some embodiments.

With continuing reference now to FIGS. 1 and 2, sputtering source 135 can be, for example, a magnetron, an ion beam source, a RF generator, or any suitable sputtering source configured to deposit a plurality of absorber layer atoms of a first type over at least a portion of a surface of each one of the plurality of substrates 130. A power supply 180 is provided which is appropriately configured to power the particular type of sputtering source 135 selected for use.

In one embodiment, power supply 180 has an adjustable current output to sputtering source 135 which is controlled by a programmable controller 220. In some embodiments, the first sputtering source 135 includes at least one of a plurality of sputtering targets 137 positioned within view of rotating substrates 130 to deposit atoms on the substrates 130. The first sputtering source 135 can utilize an inert sputtering or carrier gas which transports the absorber layer components to the substrates 130 for depositing a film. In some embodiments, sputtering is performed with an argon gas. Other possible sputtering gases that can be used include without limitation krypton, xenon, neon, and similarly inert gases.

As shown in FIG. 1, PVD apparatus 100 includes a first sputtering source 135 disposed within view of vacuum chamber 102 that is configured and formed to deposit a plurality of absorber layer atoms of a first type over at least a portion of a surface of each one of the plurality of substrates 130, and a second sputtering source 135 disposed within view of the vacuum chamber and opposite the first sputtering source that is configured and formed to deposit a plurality of absorber layer atoms of a second type over at least a portion of a surface of each one of the plurality of substrates 130. In other embodiments, the first sputtering source 135 and the second sputtering source 135 are disposed adjacent to each other within the vacuum chamber. In some embodiments, the first and second sputtering sources 135 can each include at least one or more of a plurality of sputtering targets 137.

In various embodiments, the first sputtering source 135 is comprised of and configured to deposit a plurality of absorber layer atoms of a first type (e.g. copper (Cu)) over at least a portion of a surface of each one of the plurality of substrates 130, and the second sputtering source 135 is comprised of and configured to deposit absorber layer atoms of a second type (e.g. indium (In)) over at least a portion of a surface of each one of the plurality of substrates 130. In some embodiments, the first sputtering source 135 is configured to deposit a plurality of absorber layer atoms of a first type (e.g. copper (Cu)) and a third type (e.g. gallium (Ga)) over at least a portion of a surface of each one of the plurality of substrates 130. In some embodiments, a first sputtering source 135 includes one or more copper-gallium sputtering targets 137 and a second sputtering source 135 includes one or more indium sputtering targets 137. For example, a first sputtering source 135 can include two copper-gallium sputtering targets and a second sputtering source 135 can include two indium sputtering targets. In some embodiments, a copper-gallium sputtering target 137 includes a material of approximately 70 to 80% (e.g. 69.5 to 80.5%) copper and approximately 20 to 30% (e.g. 19.5 to 30.5%) gallium. In various embodiments, PVD apparatus 100 has a first copper-gallium sputtering target 137 at a first copper:gallium concentration and a second copper-gallium sputtering target 137 at a second copper:gallium concentration for grade composition sputtering. For example, a first copper-gallium sputtering target can include a material of 65% copper and 35% gallium to control monolayer deposition to a first gradient gallium concentration and a second copper-gallium sputtering target can include a material of 85% copper and 15% gallium to control monolayer deposition to a second gradient gallium concentration.

The sputtering targets 137 can be any suitable size and configuration. For one representative example, planar or flat rectilinear sputtering targets 137 may be provided that can measure, without limitation, approximately 10-20 cm wide and approximately 1.5-2.0 m high. Other suitable sizes may be used depending at least in part on the corresponding size of the substrates 130 to be processed.

In some embodiments, a sputtering source 135 that is configured to deposit a plurality of absorber layer atoms of indium over at least a portion of the surface of each one of the plurality of substrates 130 can be doped with sodium (Na). For example, an indium sputtering target 137 of a sputtering source 135 can be doped with sodium (Na) elements. The inventors have determined that doping an indium sputtering target 137 with sodium may minimize the need for depositing an alkali-silicate layer in the solar cell. This improvement may result in lower manufacturing costs for the solar cell as sodium is directly introduced to the absorber layer. In some embodiments, a sputtering source 135 is a sodium-doped copper source having between approximately two and ten percent sodium (e.g. 1.95 to 10.1 percent sodium). In various embodiments, an indium sputtering source 135 can be doped with other alkali elements such as, for example, potassium. In other embodiments, apparatus 100 can include multiple copper-gallium sputtering sources 135 and multiple sodium doped indium sputtering sources 135. For example, the solar cell forming apparatus can have a 65:35 copper-gallium sputtering source 135 and an 85:15 copper-gallium sputtering source 135 for grade composition sputtering.

The foregoing combination of sputtering sources 135 and targets 137 provide the CIG foundation for forming a CIGS absorber layer on a thin film solar cell substrate.

With continuing reference to FIG. 1, in various embodiments, PVD apparatus 100 further includes an evaporation source 140 configured to deposit a plurality of absorber layer atoms of a fourth type over at least a portion of the surface of each one of the plurality of substrates 130 having a deposited film comprised of CIG. In one embodiment, the fourth type is non-toxic elemental selenium and can include any suitable evaporation source material. In some embodiments, evaporation source 140 is configured and operable to produce a vapor of an evaporation source material of the fourth type. The vapor can condense upon the one or more substrates 130 to complete the CIGS absorber layer. For example, the evaporation source 140 can be an evaporation boat, crucible, filament coil, electron beam evaporation source, or any suitable evaporation source 140. In some embodiments, the evaporation source 140 is disposed in a first subchamber of the vacuum chamber 102. In various embodiments, the vapor of the fourth type evaporation source material can be ionized, for example using an ionization discharger, prior to condensation over the substrate to increase reactivity. In the illustrated embodiment, first and second sputtering sources 135 are disposed on opposing sides of the vacuum chamber 102 and substantially equidistant from evaporation source 140 about the perimeter of the vacuum chamber 102.

Referring to FIG. 1, in various embodiments, PVD apparatus 100 further includes a first isolation source such as isolation pump 152 which is configured and operable to isolate evaporation source 140 from a first sputtering source 135. The first isolation source can be configured to prevent the fourth type material from evaporation source 140 (e.g. selenium) from contaminating the first sputtering source 135. In the illustrated embodiment, the isolation pump 152 may be, for example, a vacuum pump. In other embodiments, the apparatus 100 can include a plurality of isolation pumps 152.

In some embodiments, the first isolation pump 152 is disposed within a first subchamber 102 fluidly communicating with vacuum chamber 102 (see FIG. 1). Isolation pump 152 is operable to maintain a pressure in the first subchamber 102 that is lower than the pressure within the vacuum chamber 102 outside of the first subchamber, thereby diverting the flow of gases and vapor from evaporation source 140 into the subchamber. The isolation source comprising isolation pump 152 is disposed between evaporation source 140 and sputtering source 135 to intercept and evacuate atoms (e.g. vaporized selenium source material atoms) from the vacuum chamber 102 that were introduced by the evaporation source to prevent contamination of the sputtering source 135. For example, isolation source 152 can be a vacuum pump 152 disposed within a first subchamber of the vacuum chamber housing the evaporation source 140 and configured to evacuate evaporation source material atoms to prevent contamination of a sputtering source 135.

In various embodiments including a plurality of sputtering sources 135 and/or a plurality of evaporation sources 140, PVD apparatus 100 can include a plurality of isolation sources such as isolation vacuum pump 152 to isolate each of the evaporation sources from each of the sputtering sources 135 as shown in FIG. 1. For example, in embodiments having first and second sputtering sources 135 as shown disposed on opposing sides of a vacuum chamber 102 and a first and second evaporation source 140 each disposed there between on a perimeter surface of the vacuum chamber 102, apparatus 100 can include a first isolation pump 152 disposed between the first sputtering source 135 and evaporation source 140 and a second isolation pump 152 disposed between the second sputtering source 135 and evaporation source 140. In the illustrated embodiment, accordingly, apparatus 100 includes an isolation pump 152 disposed between evaporation source 140 and one of the two sputtering sources 135.

The PVD apparatus 100 can further include one or more heaters 117 to heat the plurality of substrates 130 disposed on a plurality of surfaces 122 of the rotatable drum 120 as shown in FIG. 1. In the illustrated embodiment, the heaters 117 are disposed in and supported by a heater apparatus 115 configured to position a heater proximate each substrate 130. Heater apparatus 115 can have a shape that is substantially conformal with the shape of the rotatable drum 120. In the illustrated embodiment, the plurality of heaters 117 are shown positioned in a substantially octagonal shape arrangement within a heating apparatus 115. However, the heater apparatus 115 can have any other suitable shape. In various embodiments, the heater apparatus 115 is disposed to maintain a substantially uniform distance about the perimeter of the substrate apparatus 120. In the illustrated embodiment, heater apparatus 115 is disposed about an interior surface of the rotatable substrate apparatus 120, and more specifically in some embodiments heaters 117 are disposed on the interior side of rotatable drum 120 behind vertical substrate support surfaces 122. One or more additional individual heaters 117 may further be disposed at various locations about an exterior surface of rotatable drum 110 to provide supplemental heating. In other possible embodiments, the heater apparatus 115 containing the plurality of heaters 117 can be disposed about an exterior surface of a rotatable drum 110.

A suitable commercially-available electric power source is provided for heater apparatus 115 which can include electric leads which through a surface of the rotatable drum 110, and/or from underneath or above the drum to energize the heaters 117.

In various embodiments, with continuing reference to FIG. 1, the substrate support drum 120 is rotatable around the heater apparatus 115 which remains stationary within housing 105 of PVD apparatus 100. In other embodiments, the heater apparatus 115 with plurality of heaters 117 can be rotatable along with drum 120. Heaters 117 can include, but are not limited to, infrared heaters, halogen bulb heaters, resistive heaters, or any suitable type heaters for heating a substrate 130 during a deposition process. In some embodiments, the heater apparatus 115 can heat a substrate 130 to a temperature between approximately 300 and 550 degrees Celsius (e.g. 295 and 555 degrees Celsius).

As shown in FIG. 1, apparatus 100 can further include an isolation baffle 170 disposed about the evaporation source 140. Isolation baffle 170 can be configured to guide and direct a vapor of an evaporation source material (e.g. selenium) to a particular portion of a surface of the plurality of substrates 130. Isolation baffle 170 can further be configured to direct a vapor of an evaporation source material away from a sputtering source 135 to prevent contaminating one or more sputtering sources 135 with evaporation source material 122. In some embodiments, the isolation baffles 170 can be composed of a material such as, for example, stainless steel or other similar metals and metal alloys. In some embodiments, the isolation baffle 170 is disposable. In other embodiments, the isolation baffle 170 is cleanable.

In some embodiments, referring to FIG. 1, PVD apparatus 100 can include one or more in-situ monitoring devices 160 applied to one or more portions of the apparatus to monitor process parameters such as temperature, chamber pressure, film thickness, rotary drum 120 position and speed, electric power supply current to targets 137, or any other suitable process parameter of interest in controlling and monitoring the operation of apparatus 100. In various embodiments, apparatus 100 can include a load lock chamber 182 and/or an unload lock chamber 184. In embodiments of the present disclosure, apparatus 100 can include a buffer chamber 155 for providing a vacuum break and communication with internal vacuum chamber 102 in housing 105 to load/unload solar cell substrates 130.

Referring to FIG. 1, PVD apparatus 100 includes a programmable controller 220 in some embodiments which is configured and operable to control the operation of the apparatus and film deposition process. Controller 220 includes an appropriately configured programmable computer data processor such as a central processing unit (CPU) or multiple microprocessors (MPU) in some embodiments, control circuits and buses, machine readable non-transitory storage medium (e.g. optical and magnetic storage devices such as hard disks, CD-ROM, DVD, magnetic tape/cartridges, USB, RAM, etc.), volatile and non-volatile memory (e.g. ROM and RAM), input devices (e.g. keyboard, mouse, control buttons, etc.), output devices (e.g. visual displays, printers, etc.), wired and wireless communication interfaces, power supply, etc. as will be known to those skilled in the art to provide a fully functional controller for the intended present application. Controller 220 is operable to receive data input signals from the monitoring devices 160, communication interfaces, and input devices, and to provide output data and control signals to PVD apparatus 100 or related appurtenances associated with apparatus 100. The machine readable medium is encoded with computer-executable instructions which, when read and executed by the processor 220, configure and cause the processor to direct and control various operations of PVD apparatus 100 and related appurtenances including those more specifically elaborated herein.

According to a first aspect of the present disclosure, FIGS. 2-5 show one embodiment of a device for improving vertical absorber layer film thickness uniformity in the vertical direction from top to bottom edge along the substrate 130. In one embodiment, PVD apparatus 100 includes at least one specially configured shield plate 230 with flow aperture 232 disposed between the sputtering source target 137 and substrate 130 inside vacuum chamber 102. Shield plate 230 is operative to control and distribute the flow of inert carrier gas with film compounds entrained therein, and correspondingly control the resulting film thickness uniformity of materials (i.e. atoms) deposited onto the rotating substrate 130 carried by substrate support drum 120. FIGS. 3 and 4 are top plan views of a portion of shielding box enclosure 250 and related appurtenances. FIG. 5 is a front elevation view of box enclosure 250 and shield plate 230.

Referring to FIGS. 2-5, shield plate 230 is mounted to front wall 251 of box enclosure 250 in one embodiment and effectively closes frontal opening 258 (see FIG. 2) with exception of flow aperture 232. Shield plate 230 defines a top edge 231, bottom edge 233, and pair of longitudinally extending side edges 235 spanning therebetween. In one embodiment, shield plate 230 has a substantially flat or planar body with parallel front and rear surfaces 234, and a length and width substantially larger than the plate's thickness. In some embodiments, shield plate 230 has a rectilinear shape which may be rectangular or square. Other suitable shapes may be provided.

Shield plate 250 may be made of any suitable material, including for example metals such as stainless steel in some embodiments. Shield plate 230 can be attached to box enclosure 250 by any suitable method including for example without limitation welding or mechanical fasteners. In one embodiment, shield plate 230 is attached to front wall 251 of box enclosure 250 as shown.

As best shown in FIGS. 2 and 5, flow aperture 232 is vertically elongated in one embodiment having a height H1 that is larger than a maximum width W1 or W2. W1 is defined as the width at the top end 237 and bottom end 238 of aperture 232. W2 is defined as a width between the top and bottom ends 237, 238.

In one embodiment, flow aperture 232 has an hour glass shape having a minimum width W2 smaller than widths W1 at the top or bottom ends 237, 238 (see FIGS. 2 and 5). In one embodiment, a minimum width W2 of aperture 232 is located at the vertical midpoint of the aperture at the mid-height H2 which is defined as one-half of height H1. The sides 236 of the flow aperture 232 in some embodiments have an arcuate, inwardly convex shape with the narrowest point between the sides being located at approximately mid-height H2 in one embodiment. In other embodiments, the narrowest point or width W2 measured between sides 236 may be above or below the mid-height H2. Accordingly, the width W2 in some embodiments of flow aperture 232 is smaller in the middle portion between the top and bottom ends 237, 238 than at the top and bottom.

Advantageously, the inventors have discovered that the inwardly convex shaped flow aperture 232 shown in FIGS. 2 and 5 produces better vertical film thickness uniformity on substrate 130 from top to bottom edges than an aperture with straight sides. The film thickness, which on large substrates tends to be thicker proximate to the top and bottom edges, is more uniform and consistent with film thicknesses in the more central portions of the substrate.

According to a second aspect of the present disclosure, the absorber layer film thickness uniformity in the horizontal direction along the substrate can be improved by mechanically operated shutters 300 whose position is synchronized with the rotation of rotating drum 120 on which substrates 130 are mounted during processing in PVD apparatus 100.

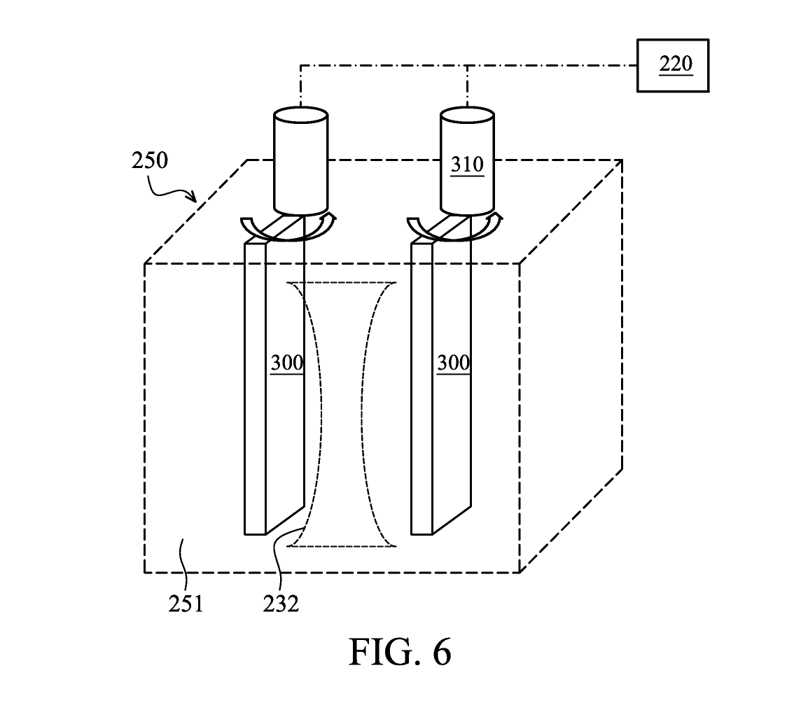

FIGS. 3 and 4 show top plan views inside box enclosure 250. FIG. 6 is a perspective view of box enclosure 250. Referring to these figures, a pair of opposing and vertically oriented shutters 300 is pivotably mounted in enclosure 250 about a pivot point P. In one embodiment, pivot point P may be defined by a drive shaft of an electric servomotor 310 provided as part of a servomechanism operable to rotate or pivot shutters 300 for controlling their position with respect to box enclosure 250. In one embodiment, one servomotor is provided for each shutter 300. Servomotors 310 are mounted on and supported by box enclosure 250 such as top wall 254 in some embodiments, and shutters 300 in turn are each movably coupled to and supported by the drive shaft of the servomotors. Servomotors and servomechanism are well known to those skilled in the art without further elaboration.

In one embodiment, as shown, pivot point P may be located at the rearmost end of each shutter 300 to provide maximum movement to the opposing forward end of the shutter nearest the vacuum chamber 102 of PVD apparatus 100. In other embodiments, pivot point P may be located between the ends of each shutter including near the midpoint.

In one embodiment, shutter 300 is shaped as a substantially straight and flat blade which has an overall rectangular configuration and cross-section in a horizontal plane. Other suitable polygonal and non-polygonal overall and cross-sectional shapes may be used. Shutter 300 may be made of any suitable material including metals, such as without limitation stainless steel, aluminum, or titanium as some non-limiting examples.

With continuing reference to FIGS. 3, 4, and 6, the pair of shutters 300 act as a variable venturi or orifice to regulate the amount of inert sputtering or carrier gas flow therethrough with film compounds or atoms (e.g. film components) entrained therein into the vacuum chamber 102 of PVD apparatus 100. This in turn allows the absorber layer film thickness deposited on structure 130 to be controlled at any given time as the structure rotates past each target 237 in box enclosure 250. In one embodiment, shutters 300 are equally positioned and aligned on opposite sides of flow centerline CL defined by flow aperture 232 in shield plate 230 as best shown in FIGS. 3 and 4.

The position and movement of shutters 300 is controlled by servomotors 300, which in one embodiment is controlled by programmable controller 220 already describe herein which controls the sputtering process. Shutters 300 are pivotably moveable between a fully open position as shown in FIG. 3 and a closed position as shown in FIG. 4. The closed position may be a partially closed position to allow less flow of carrier gas with film deposition components to exit box enclosure 250 and enter vacuum chamber 102 than when the shutters are in their fully open position. In the fully open position, shutters 300 are each oriented substantially parallel to shield plate 230 and front wall 251 of box enclosure 250. In the partially closed position, shutters 300 are oriented at angle to shield plate 230 and front wall 251 of box enclosure 250.

In one embodiment, pivoting movement of each of the shutters 300 is controlled by controller 220 to occur simultaneously and in synchronization or unison so that the shutters move together resulting in each shutter being oriented at the same angle to shield plate 230 (or frontal opening 258 if the embodiment does not include a shield plate). In other possible embodiment, differential pivoting movement of each shutter 300 may be provided so that each shutter is opened at a different angle to the shield plate or frontal opening. In some embodiments, one or the other shutter 300 may pivotably be moved while the remaining shutter remains stationary. Controller 220 may be programmed to provide any of the foregoing types of operation depending on the needs of the particular application at hand. In one embodiment, both shutters move simultaneously and in unison together.

During prior PVD processes without the benefit of gas flow shutters as disclosed herein, as the substrates 130 rotate on drum 120, the side edges 133 of the substrate pass closer to the targets 137 and box enclosure 250 than the more central portions of the substrate as shown in FIGS. 3 and 4. This detrimentally deposits a greater thickness of absorber layer film at the side edges 133 (i.e. horizontal direction) than the central regions therebetween because the carrier gas flow exiting the front opening 258 of the box enclosure 250 is substantially constant regardless of the position of the structure being processed. The non-uniform film thicknesses of the active absorber layer across over the surface of the substrate accordingly decreases solar cell energy conversion efficiency and performance. The non-uniformity problem is more acute with larger substrates.

To compensate for the foregoing, the shutter system disclosed herein advantageously allows the carrier gas flow to the substrate 130 to be controlled (i.e. increased/decreased) as desired depending on the position of the substrate with respect to the box enclosure 250 and targets 137 to produce a more uniform film thickness. The greater the gas flow to the substrate, the thicker the resulting absorber layer film deposit will be. In one embodiment, the position of the shutters 300 is controlled by the programmable controller 220 and synchronized with the rotation of drum 130 and position of the substrate with respect to the box enclosure and targets, as follows.

FIG. 3 shows substrate 130 centered with respect to box enclosure 250 and targets 137. When the central region 303 of the substrate 130 is closest to the frontal opening 258, and in some embodiments flow aperture 232 in shield plate 230 if provided, the shutters 300 are in a fully open position to maximize gas flow to the substrate (see FIG. 3). As trailing side edge 133 of the substrate nears the front opening or flow aperture of the box enclosure 250 as shown in FIG. 4, shutters 300 begin to close via operation of the servomotors 310 controlled by controller 220 and move towards a partially closed position as shown. The flow of carrier gas with absorber layer components is thereby decreased so that as trailing side edge 133 passes by the box enclosure 250, the thickness of film deposited is reduced.

The shutters 300 remain in the partially closed position shown in FIG. 4 as the leading edge 133 of the next substrate 130 approaches the box enclosure 250. As the substrate 130 continues to rotate, the central region 303 of substrate approaches the position shown in FIG. 3 and the shutters 300 are returned to their fully open position.

It will be appreciated that the forgoing opening and closing cycles of the shutters 300 may occur rapidly as the rotating drum 120 with substrates 130 mounted thereon rotate past the box enclosures 250 and targets 137. The duration of the cycles will directly correspond with the speed of rotation of the drum 120 (i.e. RPM or revolutions per minute), and be controlled by the controller 220 so that the shutters 300 are in their proper foregoing positions (i.e. partially closed or fully open) depending on the orientation and position of the substrate 130 with respect to the box enclosure 250. Accordingly, in one embodiment, programmable controller 220 is programmed and configured to achieve the foregoing operation of the shutters 300 when processing substrates. Using controller 220, the shutter operation may be implemented in hardware, firmware, software, or combinations thereof.

According to a third aspect of the present disclosure, the absorber layer film thickness uniformity in the horizontal direction can be improved by electronically controlling the electric sputtering power supply which is synchronized with the spinning or rotating drum 120 speed or RPM. The absorber layer film thickness deposited on substrate 130 is proportional to the intensity or level of power supplied to sputtering source 135 by power supply 180 (see FIG. 1). Accordingly, controlling the power supply or current to sputtering source 135 permits the film thickness on substrate 130 to be controlled and adjusted at any given point in time as the substrate rotates past the box enclosure 250 and sputtering source targets 137.

In one embodiment, with continuing reference to FIG. 1, the power supply 180 is adjustable so that the power output or current to sputtering source 135 and targets 137 is controllable. In one embodiment, programmable controller 220 is programmed to control the output from power supply 180. Using controller 220, the power level regulation may be implemented in hardware, firmware, software, or combinations thereof.

In a somewhat analogous manner to regulation of the inert gas flow using shutters 300 as shown in FIGS. 3 and 4 described above, controller 220 cyclically increases and decreases the power output to sputtering source 135 depending on the orientation and position of the substrate with respect to the targets 137 and box enclosure 250 in a manner that avoids depositing greater thicknesses of absorber layer film at the substrate vertical edges 133 than in the central regions 303 (see FIGS. 3, 4, and 7). When the substrate 130 is in the position shown in FIG. 3, the power supply to sputtering source 135 is at an increased or maximum level to deposit absorber layer film on the central region 303 of the substrate. As the trailing edge 133 of the substrate approaches target 137 as shown in FIG. 4, controller 220 decreases the power supply to sputtering source 135 to a decreased or minimum level. This decreases the reactivity of the PVD process and less absorber layer film is therefore deposited on the substrate surface proximate to edges 133. The power level remains at this decreased or minimum level as the leading edge 133 of the next substrate 130 to be processed approaches the target 137 until the central region approaches the target as shown in FIG. 3. Controller 220 then increases the power level to maximum for forming the absorber layer on the central region 303 of the substrate.

Manipulation of the PVD process power level in the foregoing manner advantageously produces a more uniform horizontal film absorber layer film thickness from vertical edge to vertical edge 133 of the substrate 130.

According to a fourth aspect of the present disclosure, the absorber layer film thickness uniformity in the horizontal direction along the substrate can be improved by adjusting the rotational speed or RPM of drum 120 which is synchronized with the distance between the rotating substrate and the stationary target 137. The absorber layer film thickness deposited on substrate 130 is proportional to the exposure time of the substrate in proximity of the target 137 mounted in box enclosure 137 (see FIG. 1). The longer the exposure time, the greater the thickness of absorber layer film will be deposited on the substrate. Accordingly, controlling the RPM of rotating drum 120 on which the substrates are mounted will therefore increase or decrease the exposure time of the substrates to the target 137. This permits the film thickness on substrate 130 to be controlled and adjusted at any given point in time as the substrate rotates past the box enclosure 250 and sputtering source targets 137.

In one embodiment, with continuing reference to FIG. 1, the rotational speed (RPM) of drum 120 is controlled by programmable controller 220 which is programmed and configured to vary or adjust the drum speed as the substrates each pass by targets 137. The RPM of the drum 120 will therefore cyclically vary over time depending on whether the vertical edges 133 or central region 303 of the substrate 130 is closest to targets 137. Using controller 220, the drum rotational speed control may be implemented in hardware, firmware, software, or combinations thereof.

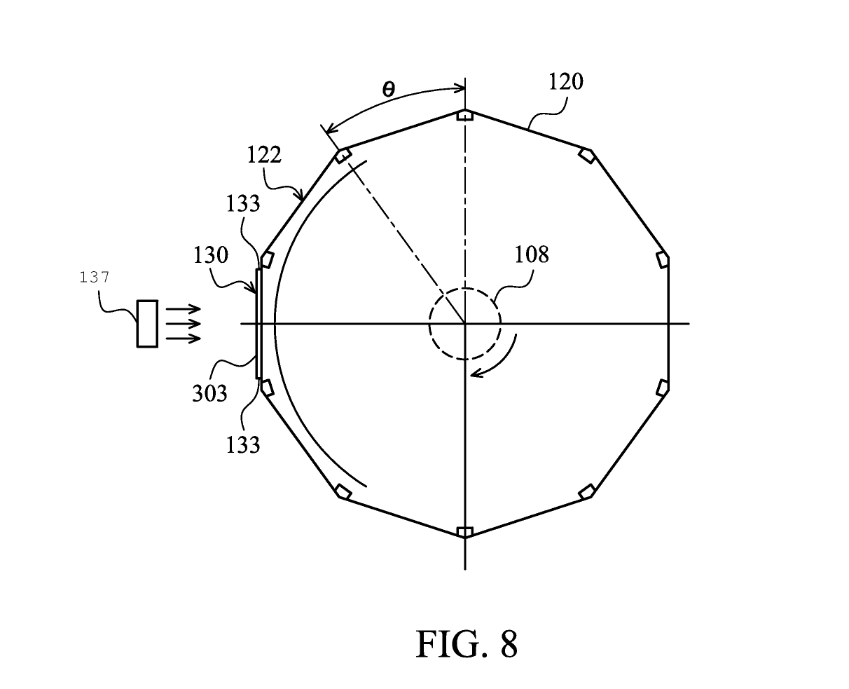

For purposes of readily illustrating the variable drum speed embodiment, FIG. 8 is a top view of a 10-sided or decagon shaped rotatable drum 120 driven by electric motor drive 108. Ten substrates 130 are mounted one each on a corresponding vertical substrate support surfaces 122. Each support surface 122 represents a segment of a circle and occupying a sector having a central rotational angle Θ of 36 degrees. As drum 120 rotates past target 137, each substrate 130 will be exposed to the target for depositing an absorber layer film over an arc of 36 degrees.

In a somewhat analogous manner to regulation of the inert gas flow using shutters 300 as shown in FIGS. 3 and 4, or the power supply level to sputtering source 135 as described above, controller 220 cyclically increases and decreases the rotational speed or RPM of drum 120 depending on the orientation and position of the substrate 130 (i.e. central region 303 or vertical edges 133) with respect to the target 137 and box enclosure 250 in a manner that avoids depositing greater thicknesses of absorber layer film at the substrate vertical edges 133 than in the central regions 303 (see, e.g. FIGS. 3 and 4 showing positions of the substrate with respect to the target).

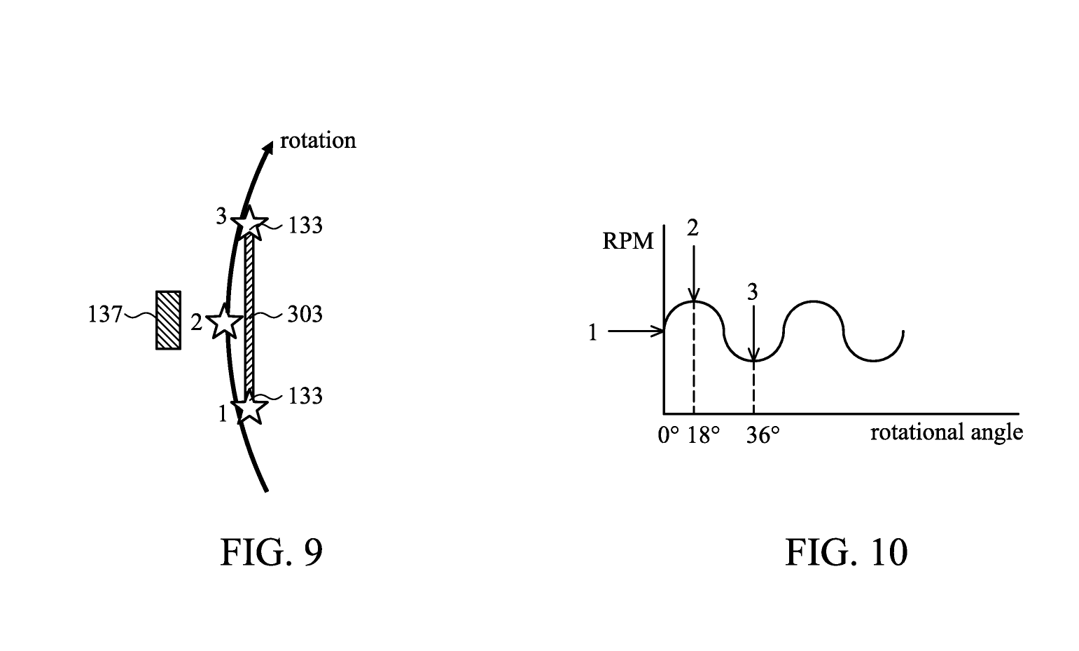

FIGS. 9 and 10 will further facilitate description of the variable drum speed embodiment.

FIG. 9 is a top diagrammatic view showing three rotational reference Points 1-3 along a circular path of motion circumscribed by the rotating vertical edges 133 of substrate 130 about drum 120.

FIG. 10 is a drum speed graph indicative of the results of programming and configuring controller 220 to control the drum speed. In one embodiment, as shown, controller 220 is programmed and configured so that the drum 120 speed follows a sinusoidal shaped curve as shown.

Operation of the variable drum speed embodiment will now be described. Referring to FIGS. 8-10, when the leading edge 133 of the substrate 130 first is positioned at Point 1 (corresponding to a 0 degree rotational angle in FIG. 10), the rotational speed (RPM) of drum 120 is at its lowest or normal baseline speed as shown in FIG. 10 (see, e.g. Point 1 (0 degrees) and Point 3 (36 degrees)). When leading edge 133 approaches Point 2 (18 degrees), the speed is increased as shown in FIG. 10 to a higher or maximum level because the edge will be in closest proximity to target 137 that would result in a thicker deposition of absorber layer film near the edge if the speed of drum 120 were to remain constant. The increase in speed reduces the exposure time to target 137, and there decreases the thickness of absorber layer film formed on the substrate edge 133.

When the leading edge 133 next approaches Point 3 (36 degrees), the speed (RPM) of drum 120 is decreased back to the baseline level as shown in FIG. 10. The central region 303 of substrate 130 is now closet to target 130 being located at Point 2 (18 degrees). The absorber layer film is deposited at the normal rate because the central region will not pass as close to the target as the leading or trailing edges 133 (see position of substrate in FIG. 9 and arcuate path of motion).

When central region 303 of the substrate is at Point 2 closest to target 137 as shown in FIG. 9, trailing edge 133 is situated at Point 1. As substrate 130 continues to rotate, the trailing edge 133 will next approach Point 2 (18 degrees in FIG. 10). The drum 120 speed is increased again by controller 220 so that the trailing edge portions of substrate 130 receive less absorber layer film.

Manipulation of the rotating drum 120 speed (RPM) in the foregoing manner advantageously produces a more uniform horizontal film absorber layer film thickness from vertical edge to vertical edge 133 of the substrate 130. It will be appreciated that the same methodology applies to drums 120 having any number of flat sides or vertical substrate support surfaces 122. Accordingly, possible embodiments of a speed control system according to the present disclosure are expressly not limited to drums having 10 sides which is just one non-limiting example.

Various embodiments of a sputtering system and PVD apparatus according to the present disclosure may include one or more of the horizontal and vertical absorber layer film thickness uniformity improvements in combination, or embodiments may use any one of the improvements alone depending on the needs of the particular application at hand.

It will be appreciated that PVD apparatus 100 of FIG. 1 can also be used to form solar cells having different type absorber layer films other than CIGS disclosed herein by selecting different sputtering and evaporation sources 135, 140 materials. Accordingly, embodiments of the present disclosure are expressly not limited to forming CIGS absorber layers alone.

According to one exemplary embodiment, an apparatus for forming a material film on a solar cell substrate is provided. The apparatus includes a housing defining a vacuum chamber, a rotating drum disposed in the vacuum chamber and defining a plurality of substrate support surfaces each configured for holding a rigid substrate to be processed, a sputtering source operably coupled to the vacuum chamber and provided with a sputtering gas for transporting material film components to the vacuum chamber, a sputtering target associated with the sputter source and containing material film components, and a shield plate mounted in the housing between the sputtering target and vacuum chamber. The shield plate includes an elongated flow aperture in fluid communication with the sputtering source and vacuum chamber. The flow aperture has opposing ends with a width and a middle portion having a width smaller than at least one end.

According to another exemplary embodiment, a second apparatus for forming a material film on a solar cell substrate includes a housing defining a vacuum chamber, a rotating drum disposed in the vacuum chamber and defining a plurality of substrate support surfaces each configured for holding a rigid substrate to be processed, a sputtering source operably coupled to the vacuum chamber and provided with a sputtering gas for transporting material film components to the vacuum chamber, a sputtering target associated with the sputter source and containing material film components, and a pair of flow shutters fluidly disposed between the sputtering target and the vacuum chamber. The shutters are pivotably moveable between an open position and a closed position.

According to another exemplary embodiment, an apparatus for forming a material film on a solar cell substrate includes a housing defining a vacuum chamber, a rotating drum disposed in the vacuum chamber and defining a plurality of substrate support surfaces each configured for holding a rigid substrate to be processed, a variable speed motor drive operably coupled to the drum and configured to rotate the drum at more than one rotational speed, the motor drive rotating the drum at a baseline speed level, a sputtering source operably coupled to the vacuum chamber and provided with a sputtering gas for transporting material film components to the vacuum chamber, a sputtering target associated with the sputter source and containing material film components, and a programmable controller operably connected to the motor drive. The controller operates to increase or decrease the rotational speed of the drum in synchronization or unison with the position of the substrate on the rotating drum with respect to the target.

According to another exemplary embodiment, an apparatus for forming a material film on a solar cell substrate includes a housing defining a vacuum chamber, a rotating drum disposed in the vacuum chamber and defining a plurality of substrate support surfaces each configured for holding a rigid substrate to be processed, a sputtering source operably coupled to the vacuum chamber and provided with a sputtering gas for transporting material film components to the vacuum chamber, an electrical power supply coupled to the sputtering source, the power supply operative to produce a baseline power level of the sputtering source, a sputtering target associated with the sputter source and containing material film components, and a programmable controller operably connected to the power supply. The controller operates to increase or decrease the power level of the sputtering source in synchronization or unison with the position of the substrate on the rotating drum with respect to the target. The shutters open and close in synchronization to rotation of the rotating drum for regulating flow of sputtering gas therethrough to the vacuum chamber to control the thickness of material film deposited on the substrate.

While the foregoing description and drawings represent exemplary embodiments of the present disclosure, it will be understood that various additions, modifications and substitutions can be made therein without departing from the spirit and scope and range of equivalents of the accompanying claims. In particular, it will be clear to those skilled in the art that the present disclosure can be embodied in other forms, structures, arrangements, proportions, sizes, and with other elements, materials, and components, without departing from the spirit or essential characteristics thereof. In addition, numerous variations in the methods/processes and/or control logic as applicable described herein can be made without departing from the spirit of the disclosure. One skilled in the art will further appreciate that the disclosure can be used with many modifications of structure, arrangement, proportions, sizes, materials, and components and otherwise, used in the practice of the disclosure, which are particularly adapted to specific environments and operative requirements without departing from the principles of the present disclosure. The presently disclosed embodiments are therefore to be considered in all respects as illustrative and not restrictive, the scope of the disclosure being defined by the appended claims and equivalents thereof, and not limited to the foregoing description or embodiments. Rather, the appended claims should be construed broadly, to include other variants and embodiments of the disclosure, which can be made by those skilled in the art without departing from the scope and range of equivalents of the disclosure.

What is claimed is:

1. An apparatus for forming a material film on a solar cell substrate, the apparatus comprising:
a housing defining a vacuum chamber;
a rotating drum disposed in the vacuum chamber and defining a plurality of substrate support surfaces each configured for holding a rigid substrate to be processed;
a sputtering source operably coupled to the vacuum chamber and provided with a sputtering gas for transporting material film components to the vacuum chamber;
a sputtering target associated with the sputter source and containing material film components; and
a shield plate mounted in the housing between the sputtering target and vacuum chamber, the shield plate including an elongated flow aperture in fluid communication with the sputtering source and vacuum chamber, the flow aperture having opposing ends with a width and a middle portion having a width smaller than at least one end.

2. The apparatus of claim 1, wherein the middle portion defines a minimum width of the aperture that is located at about the mid-height of the aperture.

3. The apparatus of claim 1, wherein the flow aperture has a generally hour glass shape that includes a pair of inwardly convex shaped sides extending between the ends.

4. The apparatus of claim 3, wherein the material film components are absorber layer components.

5. The apparatus of claim 1, wherein the sputter gas flows through the middle portion of the flow aperture to deposit a material film on the substrate at a reduced rate of flow than other portions of the aperture.

6. An apparatus for forming a material film on a solar cell substrate, the apparatus comprising:
a housing defining a vacuum chamber;
a rotating drum disposed in the vacuum chamber and defining a plurality of substrate support surfaces each configured for holding a rigid substrate to be processed;
a sputtering source operably coupled to the vacuum chamber and provided with a sputtering gas for transporting material film components to the vacuum chamber;
a sputtering target associated with the sputter source and containing material film components; and
a pair of flow shutters fluidly disposed between the sputtering target and the vacuum chamber, the shutters being pivotably moveable between an open position and a closed position;
wherein the shutters open and close in synchronization to rotation of the rotating drum for regulating flow of sputtering gas therethrough to the vacuum chamber to control the thickness of material film deposited on the substrate.

7. The apparatus of claim 6, wherein the shutters move to the open position when a central region of the substrate passes by the target.

8. The apparatus of claim 7, wherein the shutters move to the closed position when an edge of the substrate passes by the target.

9. The apparatus of claim 8, wherein the speed with which the shutters oscillate between the open and closed positions changes in proportion to a speed of rotation of the rotating drum.

10. The apparatus of claim 6, wherein the position of the shutters is controlled by a programmable controller.

11. The apparatus of claim 10, wherein the controller controls operation of at least one servomotor operably coupled to at least one of the shutters.

12. The apparatus of claim 6, wherein the shutters are each configured as a straight blade, the shutters being oriented perpendicular to a front flow opening disposed between the shutters and vacuum chamber.

13. The apparatus of claim 6, wherein the material film components are absorber layer components.

14. An apparatus for forming a material film on a solar cell substrate, the apparatus comprising:
a housing defining a vacuum chamber;
a rotating drum disposed in the vacuum chamber and defining a plurality of substrate support surfaces each configured for holding a rigid substrate to be processed;
a variable speed motor drive operably coupled to the drum and configured to rotate the drum at more than one rotational speed, the motor drive rotating the drum at a baseline speed level;
a sputtering source operably coupled to the vacuum chamber and provided with a sputtering gas for transporting material film components to the vacuum chamber;
a sputtering target associated with the sputter source and containing material film components; and
a programmable controller operably connected to the motor drive, the controller operating to increase or decrease the rotational speed of the drum in synchronization with the position of the substrate on the rotating drum with respect to the target.

15. The apparatus of claim 14, wherein when an edge of the substrate approaches the vicinity of the target, the rotational speed of the drum is increased above the baseline speed level.

16. The apparatus of claim 15, wherein when the edge of the substrate leaves the vicinity of the target, the rotational speed of the drum is decreased to the baseline speed level.

17. The apparatus of claim 14, wherein the rotational speed of the drum remains at the baseline speed level when a central portion of the substrate approaches the vicinity of the target.

18. The apparatus of claim 14, wherein the controller controls the rotational speed of the drum in a manner that increases and decreases the speed in accordance with a sinusoidal curve of speed versus rotational angle of the drum.

19. The apparatus of claim 14, wherein the material film components are absorber layer components.

20. An apparatus for forming a material film on a solar cell substrate, the apparatus comprising:
a housing defining a vacuum chamber;
a rotating drum disposed in the vacuum chamber and defining a plurality of substrate support surfaces each configured for holding a rigid substrate to be processed;
a sputtering source operably coupled to the vacuum chamber and provided with a sputtering gas for transporting material film components to the vacuum chamber;
an electrical power supply coupled to the sputtering source, the power supply operative to produce a baseline power level of the sputtering source;
a sputtering target associated with the sputter source and containing material film components; and
a programmable controller operably connected to the power supply, the controller operating to increase or decrease the power level of the sputtering source in synchronization with the position of the substrate on the rotating drum with respect to the target.

21. The apparatus of claim 20, wherein when an edge of the substrate approaches the vicinity of the target, the power level of the sputtering source is increased above the baseline power level.

22. The apparatus of claim 21, wherein when the edge of the substrate leaves the vicinity of the target, the power level of the sputtering source is decreased to the baseline power level.

23. The apparatus of claim 20, wherein the power level of the sputtering source remains at the baseline power level when a central portion of the substrate approaches the vicinity of the target.

24. The apparatus of claim 20, wherein the material film components are absorber layer components.

25. The apparatus of claim 24, further comprising a selenium gas source fluidly coupled to the vacuum chamber, the apparatus being configured to deposit selenium on the substrate.
